(19) United States
(12) Patent Application Publication
(10) Pub. No.: US 2007/0029577 A1
(43) Pub. Date: Feb. 8, 2007

(54) Field effect transistor and method of manufacturing the same

(75) Inventors: Atsuhiro Kinoshita, Kamakura-shi (JP); Junji Koga, Yokosuka-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/440,150

(22) Filed: May 25, 2006

(30) Foreign Application Priority Data
Aug. 2, 2005 (JP) 2005-224329

(51) Int. Cl. H01L 29/76

(52) U.S. Cl. 257/213

(57) ABSTRACT

A field effect transistor includes a first semiconductor region of a first conduction type, a gate electrode formed on the channel region of the first semiconductor region via a gate insulating film, source and drain electrodes formed to interpose the channel region, second semiconductor regions of a second conduction type formed between the source and drain electrodes and the channel region, the second semiconductor regions giving rise to an extension region of the source and drain electrodes, and third semiconductor regions of the second conduction type formed between the source and drain electrodes and each of the first and second semiconductor regions, the third semiconductor regions formed by segregation from the source and drain electrodes and having an impurity concentration higher than that of the second semiconductor regions.

### CROSS-REFERENCE TO RELATED APPLICATIONS

This application is based upon and claims the benefit of priority from prior Japanese Patent Application No. 2005-224329, filed Aug. 2, 2005, the entire contents of which are incorporated herein by reference.

### BACKGROUND OF THE INVENTION

1. Field of the Invention

The present invention relates to a semiconductor device, and more specifically to a metal-insulator semiconductor (MIS) type field effect transistor with improved source and drain regions as well as a method of manufacturing such a transistor.

2. Description of the Related Art

In order to upgrade the performance of semiconductor integrated circuits, it is essential to improve the performance of the field effect transistor, which is a structural element of each circuit. The guiding principle to achieve a higher performance of an element is the scaling, and the performance of an element has been improved by microfabrication technique. At the same time, as the microfabrication techniques advances, there rise further technical obstacles to be solved. According to the International Semiconductor Roadmap, there are even no signs of a solution for a 10-to-20 nm junction (drain extension part) of the 65-nm generation, particularly, in the source-drain part formation technique.

A serious problem in the technical development of the source-drain part is the junction leak (JL). That is, in order to suppress the punch through in transistors of the 65-nm generation, it is necessary to make the diffusion layer sufficiently shallow. However, at the same time, if the depth of the diffusion layer is decreased to such a level, an increasing of junction leak due to silicide occur at, in particular, the edge of the gate.

As described above, the development of the 65-nm generation transistor technique entails such a problem that the shallow diffusion layer fabricated to suppress the punch through causes a drastically increasing of junction leak.

### BRIEF SUMMARY OF THE INVENTION

According to an aspect of the present invention, there is provided a field effect transistor comprising:

a first semiconductor region of a first conduction type, on which a channel region is formed;

a gate electrode formed on the channel region of the first semiconductor region with a gate insulating film being formed between the gate electrode and the channel region;

source and drain electrodes formed on the first semiconductor region with the channel region of the first semiconductor region being interposed between the source and drain electrodes in a channel length direction;

a second semiconductor region of a second conduction type formed between each of the source and drain electrodes and the channel region, the second semiconductor region forming an extension region of each of the source and drain electrodes; and

a third semiconductor region of the second conduction type formed between each of the source and drain electrodes and each of the first semiconductor region and the second semiconductor region, the third semiconductor region formed by segregation from the source and drain electrodes and having an impurity concentration higher than that of the second semiconductor region.

According to another aspect of the present invention, there is provided a method of manufacturing a field effect transistor, the method comprising:

forming a gate electrode on a part of a first semiconductor region of a first conduction type with a gate insulating film interposed between the gate electrode and the part of the first semiconductor region;

forming second semiconductor regions of a second conduction type on the first semiconductor region with the gate electrode arranged between the second semiconductor regions by ion-implanting an impurity using the gate electrode as a mask, the second semiconductor regions forming source and drain extension regions, respectively;

forming sidewall insulating films on opposite side surfaces of the gate electrode after formation of the second semiconductor regions;

ion-implanting an impurity to the first semiconductor region using the gate electrode and the sidewall insulating films as a mask to form ion-implanted parts;

forming source and drain electrodes by siliciding selectively the first semiconductor region to an area deeper than the ion-implanted part; and

forming a third semiconductor region of the second conduction type having an impurity concentration higher than that of the second semiconductor region, in an interface between each of the source and drain electrodes and each of the first semiconductor region and the second semiconductor region, by segregation from the source and drain electrodes.

According to still another aspect of the present invention, there is provided a field effect transistor comprising:

a first semiconductor region of a first conduction type on which a channel region is formed;

a gate electrode formed on the channel region of the first semiconductor region with a gate insulating film interposed between the gate electrode and the channel region;

source and drain electrodes formed on the first semiconductor region with the channel region of the first semiconductor region being interposed between the source and drain electrodes in a channel length direction, the source and drain electrodes being formed of a metal silicide; and

an impurity segregation region of a second conduction type formed between the first semiconductor region and each of the source and drain electrodes, the impurity segregation region being formed by segregation of the impurity into the metal silicide.

### BRIEF DESCRIPTION OF THE SEVERAL VIEWS OF THE DRAWING

FIG. 1 is a diagram showing a cross section of an element structure of a MIS field effect transistor according to the first embodiment;

FIGS. 2A and 2B each are a schematic diagram illustrating the principle of a segregation junction forming method;

FIGS. 3A to 3D are cross sectional views illustrating steps in the manufacture of the MIS field effect transistor according to the first embodiment;

FIG. 4 is a diagram showing a cross section of an element structure of a MIS field effect transistor according to the second embodiment;

FIG. 5 is a diagram showing a cross section of an element structure of a MIS field effect transistor according to the third embodiment;

FIG. 6 is a diagram showing a cross section of another version of the element structure of the MIS field effect transistor according to the third embodiment;

FIG. 7 is a diagram showing a cross section of still another version of the element structure of the MIS field effect transistor according to the third embodiment;

FIG. 8 is a diagram showing a cross section of an element structure of a MIS field effect transistor according to the fourth embodiment;

FIGS. 9A to 9E are cross sectional views illustrating steps in the manufacture of the MIS field effect transistor according to the fourth embodiment;

FIG. 10 is a diagram showing a cross section of an element structure of a MIS field effect transistor according to the fifth embodiment;

FIG. 11 is a diagram showing a cross section of an element structure of a MIS field effect transistor according to the sixth embodiment;

FIG. 12 is a diagram showing a cross section of another version of the element structure of the MIS field effect transistor according to the sixth embodiment;

FIG. 13 is a diagram showing a cross section of still another version of the element structure of the MIS field-effect transistor according to the sixth embodiment;

FIG. 14 is a diagram showing a cross section of an element structure of a MIS field effect transistor according to the seventh embodiment;

FIGS. 15A to 15F are cross sectional views illustrating steps in the manufacture of the MIS field effect transistor according to the seventh embodiment;

FIG. 16 is a diagram showing a cross section of an element structure of a MIS field effect transistor according to the eighth embodiment;

FIG. 17 is a diagram showing a cross section of another version of the element structure of the MIS field effect transistor according to the eighth embodiment;

FIG. 18 is a diagram showing a cross section of still another version of the element structure of the MIS field effect transistor according to the third embodiment; and

FIG. 19 is a diagram showing a cross section of a general element structure of a conventional MIS field effect transistor.

### DETAILED DESCRIPTION OF THE INVENTION

Before the embodiments of the present invention are explained, a problem entailed to the development of the transistor technique of the 65-nm generation, that is, the shallow diffusion layer fabricated to suppress the punch through causes a drastically increasing of junction leak (JL), will now be described.

FIG. 19 is a cross section of an element structure of a field effect transistor having an ordinary salicide (self-aligned silicide) structure, with structural parts such as a silicon substrate 900, a gate insulating film 901, a polysilicon gate electrode 902, a gate salicide 903, a gate side wall insulating layer 904, an extension diffusion layer 905, a HALO diffusion layer 906, a deep diffusion layer 907 and a source-drain silicide 908. The source-drain region includes the elements 905 to 908. It should be noted that the source-drain region means a source region and a drain region. The elements 905 to 908 are provided on each of the source side and drain side.

The JL, which is focused on in the present invention, is a component that flows from the source-drain silicide 908 through the deep diffusion layer 907, and it mainly flows through the passage indicated by arrow in the figure. Various mechanisms have been reported as causes of the JL and the following two are considered as the main causes.

(1) When L1 is too thin or the impurity concentration in that part is too low, but the width of the depletion layer is too large, a current is created, such as direct tunnel current, trap assist tunnel current, or generation re-combination current.

(2) When metal particles are diffused from the source-drain silicide, creating a leak path, and thus a current flows.

Especially, the current created by the mechanism (1) is particularly prominent when the device includes the HALO structure.

The most effective means to suppress such a leak current is usually to increase the thickness L1 of the deep diffusion layer 907 along the path indicated by the arrow. However, in short-channel transistors, the thickness (L2 in the figure) of the deep diffusion layer 907 needs to be decreased sufficiently to suppress the punch through, and the thickness L1 is decreased as well when the L2 is decreased. This indicates that there is a certain limitation on the measures taken to decrease the JL by increasing L1. This problem becomes even more serious when the gate length is about 30 nm and the thickness (L2) of the deep diffusion layer 907 is lower than about 50 nm.

In the embodiments of the present invention, the current components created by the mechanisms (1) and (2) are drastically reduced without increasing L1, and thus the punch through and JL can be suppressed at the same time. The details of the inventions will now be described with reference to the embodiments illustrated in the accompanying drawings.

(First Embodiment)

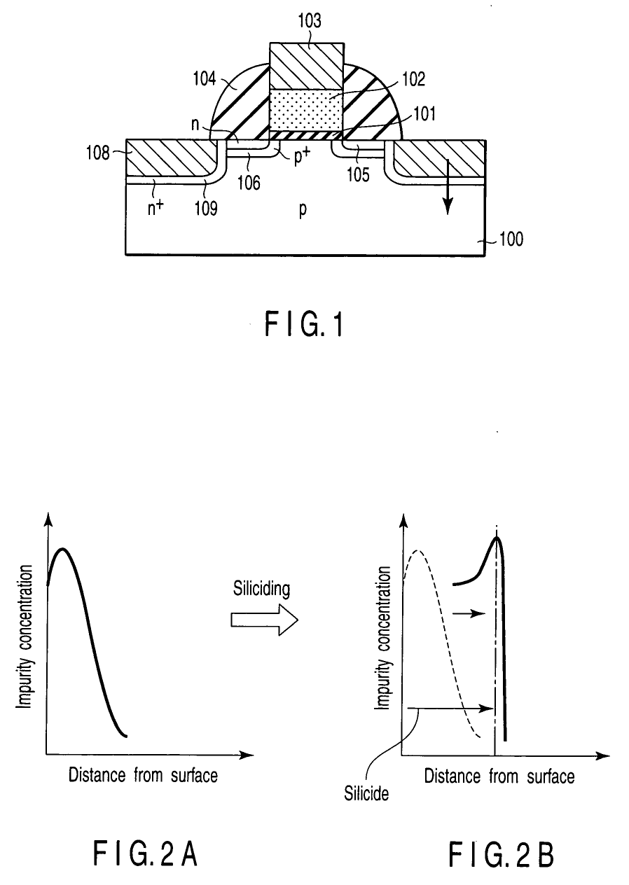

FIG. 1 is a diagram showing a cross section of an element structure of a MIS field effect transistor according to the first embodiment. The reference numerals given to the structural elements of this embodiment correspond to those shown in FIG. 19.

As shown in this figure, a polysilicon gate electrode 102 is formed on a p-type silicon substrate (the first semiconductor region) 100 via a gate insulating film 101, and further a gate silicide 103 is formed thereon. This embodiment shows a case where the gate electrode 102 is formed of polysilicon, but it is alternatively possible that the members 102 and 103 are formed of a single metal layer.

A gate sidewall insulating film 104 is formed on both side surfaces of the gate electrodes 102 and 103. Further, members 105 to 109 of the source-drain region are formed in a substrate 100 under the gate electrode 102 to interpose the channel region between them. The source-drain region includes an n-type extension diffusion layer (the second semiconductor region) 105, a p⁺-type HALO diffusion layer (the fourth semiconductor region) 106, a source-drain-silicide (source-drain electrode) 108 and an n⁺-type high-concentration impurity layer (the third semiconductor region) 109.

The structure shown in FIG. 1 is similar to that of the field effect transistor shown in FIG. 19 except that it includes the high-concentration impurity layer 109 in place of the deep diffusion layer 907.

It should be noted that the high-concentration impurity layer 109 has a steep profile at a concentration higher than a predetermined level, and the layer covers the interface between the source-drain silicide 108 and the silicon substrate 100. This is the main feature of this embodiment.

That is, the field effect transistor according to this embodiment suppresses junction leak (JL) caused by silicide in the gate edge as described above, by the high-concentration impurity layer 109. Further, the high-concentration impurity layer 109 is able to suppress the punch through at the same time, since it has a shallow junction (L2 in FIG. 19) as compared to that of the deep diffusion layer.

In order to satisfy such conditions, it is essential that the impurity concentration at the interface between the high-concentration impurity layer 109 and the source-drain silicide 108 should be 4×10¹⁹ cm⁻³, and its thickness (L1 in FIG. 19) should be no more than 10 nm.

In the case where an impurity is introduced at an extremely high concentration in a shallow region as described above, it would generally become very difficult to control the concentration and depth. However, such operation can be achieved very easily with use of, for example, the segregation junction forming method, which will now be explained.

FIGS. 2A and 2B are diagrams illustrating the mechanism of the segregation junction forming method. When siliciding an impurity-containing part of a semiconductor substrate, silicidation should be carried out to a deeper region than that of the ion-implanted area. In this manner, the impurity can be introduced at an extremely high concentration in a thin region by utilizing the segregation phenomenon. More specifically, as shown in FIG. 2A, the impurity is ion-implanted in a shallow region near the surface, and then the silicidation is carried out down to a deeper region than that of the ion implantation. In this manner, it is possible to form a high-concentration impurity region within an extremely narrow region from the end portion of the silicide. This is because the diffusion of the impurity does not occur at the silicidation temperature, but the depth of the junction and the concentration of the impurity can be controlled due to the segregation phenomenon occurring with the silicidation. Thus, if the concentration of the impurity and the depth of the junction that are caused by the first ion implantation may vary, the influence of such variations can be suppressed to a minimum level.

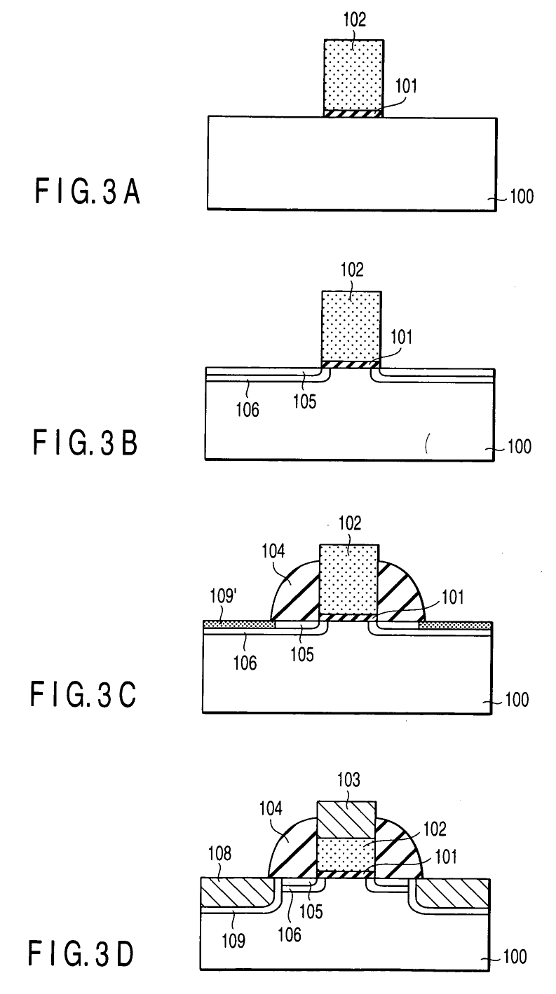

Next, the method of manufacturing the field effect transistor of this embodiment will now be described with reference to FIGS. 3A to 3D.

First, an element isolation region (not shown) is formed on the p-type silicon substrate (first semiconductor region) 100 having a surface orientation of (100), and then, the gate insulating film 101 is formed to have a thickness of about 1 nm in terms of EOT (equivalent physical oxide thickness), as shown in FIG. 3A. A polysilicon film having a thickness of about 100 to 150 nm is deposited as the gate electrode 102 on the gate insulating film 101. Subsequently, the gate insulating film 101 and gate electrode 102 are processed into a gate electrode pattern by the lithography technique, RIE, etc. If necessary, a post oxidation of about 1 to 2 nm is carried out.

Next, as shown in FIG. 3B, the n-type extension diffusion layer (the second semiconductor region) 105 and the p⁺-type HALO diffusion layer (the fourth semiconductor region) 106 are formed by ion-implanting BF₂ and As as impurities. More specifically, the extension region 105 is formed on the surface side of the substrate and the HALO diffusion layer 106 is formed on the substrate side of the extension region 105 by ion-implanting BF₂ deeper than As. If necessary, spike anneal is carried out at 1030° C. to activate the impurities.

Next, as shown in FIG. 3C, the gate sidewall insulating film 104 made of silicon nitride is formed on both sides of the gate electrode 102. More specifically, a silicon nitride layer is deposited to have a thickness of about 30 nm by the reduced pressure chemical vapor deposition (LP-CVD) method, and then the resultant is etched back by the RIE method to leave the portion of the silicon nitride layer only on the side surfaces of the gate portion. Subsequently, As is ion-implanted to have a dosage of about 2×10¹⁵ cm⁻² in the surface portion of the substrate 100, and thus an impurity layer 109′, which gives rise to the high-concentration impurity layer (the third semiconductor region), is formed. It should be noted that the sidewalls involved here has only one layer, but it is more desirable in terms of the reliability of the product to use a stack-layer sidewall including 10 nm of a TEOS oxide film, 10 nm of a silicon nitride film and 10 nm of a TEOS oxide film.

Next, as shown in FIG. 3D, Ni is sputtered to have a thickness of about 9 nm, and then a heat treatment is carried out at 450° C. for 30 seconds. In this manner, silicon of the source, drain and gate is silicided.

Thus, the source-drain-silicide 108 and the gate-silicide 103 are formed. Here, at the same time, the impurities in the layer 109′are segregated as they are silicided, and thus the high-concentration impurity layer (the third semiconductor region) 109 is formed in the interface between the source-drain silicide 108 and the silicon substrate 100. After that, unreacted Ni is removed, and thus such a structure as shown in FIG. 1 is obtained.

As described above, according to this embodiment, there is provided a field effect transistor having a salicide structure in which the interface between silicide and silicon of the source-drain section near the gate edge is covered by an impurity layer having a concentration of a predetermined level or higher and a steep concentration profile. In other words, the high-concentration and thin semiconductor region 109 is formed by the segregation from the source-drain silicide 108 in the structure having the extension region 105 between the source-drain silicide 108 and the channel region. With this structure, JL can be suppressed without providing a deep diffusion layer. In this manner, the punch through and the leak current can be suppressed, thereby making it possible to improve the reliability of the element.

(Second Embodiment)

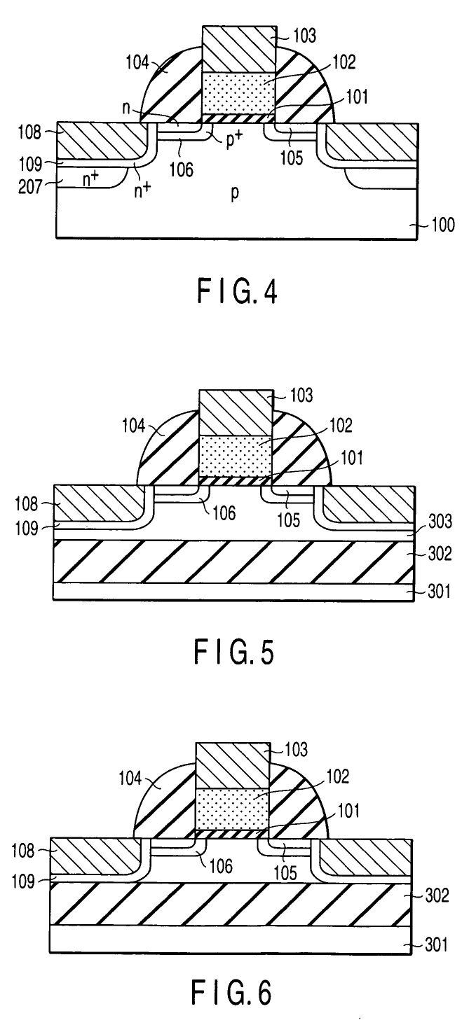

FIG. 4 is a cross sectional view of an element structure of a MIS type field effect transistor according to the second embodiment of the present invention. It should be noted that the structural elements of this embodiment that are similar to those shown in FIG. 1 are designated by the same reference numerals and the detailed descriptions therefor will be omitted here.

This embodiment can be regarded as a remodeled version of the first embodiment. That is, the structure shown in FIG. 4 is substantially identical to that of the first embodiment except that it includes an n⁺-type deep diffusion layer (the fifth semiconductor region) 207.

The structure of this embodiment, which is shown in FIG. 4 can by obtained by ion-implanting As at a higher acceleration voltage before the formation of the impurity layer 109′in the step shown in FIG. 3C.

In the first embodiment, junction leak (JL) which occurs in a section near the gate edge, can be suppressed in great deal, but the effect of suppressing JL (indicated by arrow in FIG. 1) from the bottom surface of the source-drain is still not sufficient. In order to solve this, this embodiment provides a deep diffusion layer 207 in addition to the structure of the first embodiment, thereby suppressing the JL from the bottom surface of the source-drain region. With such a structure, not only a similar effect to that of the first embodiment, but also the reliability of the element can be further improved.

(Third Embodiment)

FIGS. 5 to 7 are cross sectional views of an element structure of a MIS type field effect transistor according to the third embodiment of the present invention. It should be noted that the structural elements of this embodiment that are similar to those shown in FIG. 1 are designated by the same reference numerals and the detailed descriptions therefor will be omitted here.

A possible method to suppress junction leak (JL) from the bottom surface of the source-drain region is to form the element on an SOI substrate. Such a structure is shown in FIG. 5. The structure shown in FIG. 5 is substantially identical to that of the first embodiment except that this embodiment employs an SOI substrate. More specifically, a buried insulating film 302 such as a silicon oxide film is formed on a silicon substrate 301, and a silicon layer 303 is formed further thereon. An SOI substrate having such a structure is used as a substrate for forming an element.

In this embodiment, JL from the bottom surface is suppressed by a depletion layer, which is formed between the high-concentration impurity layer 109 and the buried insulating film 302. With this structure, the JL can be further reduced as compared to the case of the second embodiment.

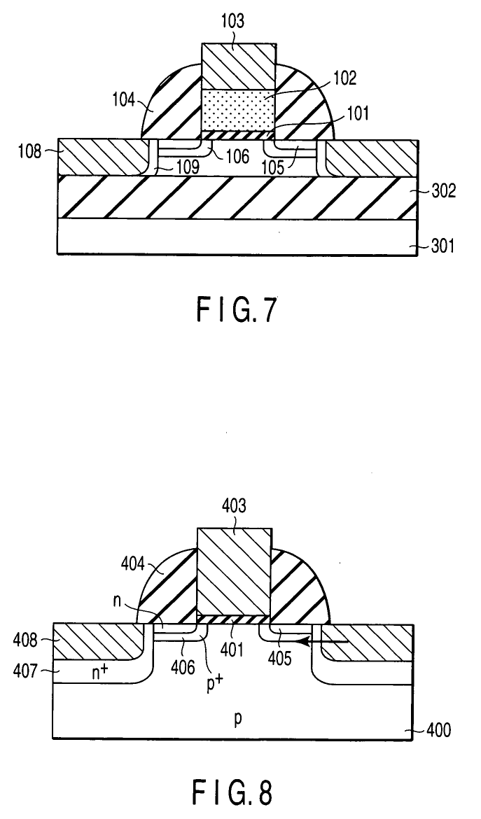

In the case of the above-described structure, the high-concentration impurity layer 109 may be in contact with the buried insulating film 302 as can be seen in FIG. 6. Further, the source-drain silicide 108 may be in contact with the buried insulating film 302 as can be seen in FIG. 7.

It should be noted that the method of manufacturing this embodiment is similar to that of the first embodiment, except that an SOI substrate is used in place of a silicon substrate. In this case, however, the thickness of the channel region and the sputtering amount of Ni need be appropriately adjusted.

(Fourth Embodiment)

FIG. 8 is a cross sectional view of an element structure of a MIS type field effect transistor according to the fourth embodiment of the present invention. It should be noted that the structural elements of this embodiment that members 400 to 408 shown in FIG. 8 correspond to the members 100 to 108 shown in FIG. 1.

The structure of the field effect transistor of this embodiment is substantially identical to that shown in FIG. 1 except that the gate electrode 102 and gate silicide 103 are replaced by a full silicide gate 403 and the source-drain silicide 408 is formed of a material having a heat resistance higher than that of the full silicide gate 403.

According to this embodiment, the heat resistance of the source-drain silicide 408 is set high, and thus it becomes possible to inhibit metal atoms from diffusing from the source-drain silicide in the direction indicated by arrow in FIG. 8 while forming the full silicide gate 403. In this manner, the junction leak (JL) can be further reduced.

An example of the combination of the materials for the full silicide gate 403 and the source-drain silicide 408, which is appropriate for the above-described object is nickel silicide for the gate and cobalt silicide for the source-drain region.

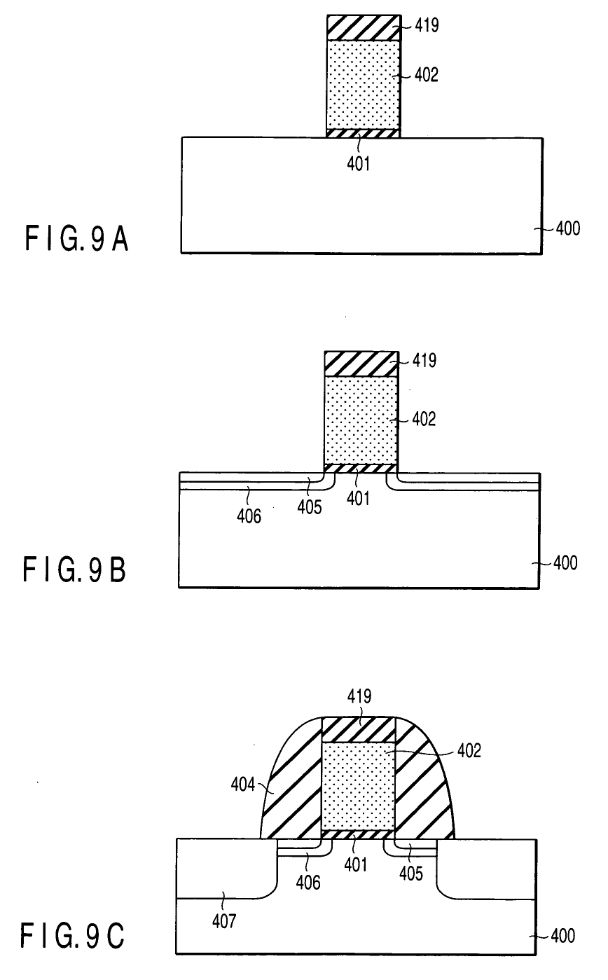

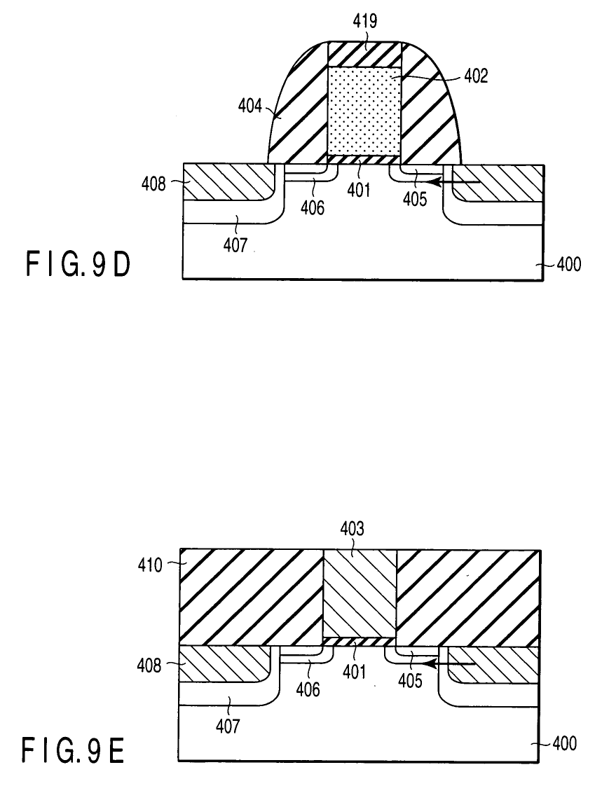

Next, the method of manufacturing the field effect transistor of this embodiment will now be described with reference to FIGS. 9A to 9E.

First, an element separation region (not shown) is formed on the p-type silicon substrate (first semiconductor region) 400, and then, the gate insulating film 401 is formed to have a thickness of about 1 nm in terms of EOT on the substrate 400, as shown in FIG. 9A. A polysilicon film having a thickness of about 100 to 150 nm is deposited as the gate electrode 402 on the gate insulating film 401. Subsequently, a silicon nitride film 419 having a thickness of about 100 nm is deposited as a gate protecting film on the gate electrode 402. Then, the gate protecting film 419, the gate electrode 402 and the gate insulating film 401 are processed into a gate electrode pattern by the lithography technique, RIE, etc. If necessary, a post oxidation of about 1 to 2 nm is carried out here.

Next, as shown in FIG. 9B, the n-type extension diffusion layer (the second semiconductor region) 405 and the p⁺-type HALO diffusion layer (the fourth semiconductor region) 406 are formed by ion-implanting BF₂ and As. If necessary, spike anneal is carried out at 1030° C. to activate the impurities.

Next, as shown in FIG. 9C, a silicon nitride layer is deposited to have a thickness of about 30 nm by the reduced pressure chemical vapor deposition (LP-CVD) method, and then the resultant is etched back by the RIE method to form the gate sidewall insulating film 404. Subsequently, As is ion-implanted to have a dosage of about 2×10¹⁵ cm⁻² to a sufficiently deep position in the substrate 400, and thus a deep diffusion layer (the fifth semiconductor region) 407, is formed. It should be noted that the sidewalls involved here has only one layer, but it is more desirable in terms of the reliability of the product to use a stack-layer sidewall including 10 nm of a TEOS oxide film, 10 nm of a silicon nitride film and 10 nm of a TEOS oxide film.

Next, as shown in FIG. 9D, Ni is sputtered to have a thickness of about 9 nm, and then a heat treatment is carried out at 500° C. for 30 seconds. In this manner, silicon of the source, drain and gate is silicided. Thus, the source-drain-silicide 408 made of cobalt silicide is formed. After that, unreacted Ni is removed.

Subsequently, as shown in FIG. 9E, a TEOS oxide film and the like are deposited as an interlayer insulating film 410, and then the upper surface of the gate electrode 402 is exposed by etching back by CMP. Next, Ni is sputtered to have a thickness of about 20 mm, and then a heat treatment is carried out at 450° C. for about 30 seconds, thereby siliciding the entire silicon in the gate electrode 402. Thus, the full silicide gate 403 made of nickel silicide is formed. After that, unreacted Ni is removed, and thus such a structure as shown in FIG. 8 is obtained.

As described above, according to this embodiment, there is provided a field effect transistor having a salicide structure as well as a full silicide gate structure, in which the silicide material of the source-drain region is one having a heat resistance higher than that of the silicide material of the gate region. With this structure, it becomes possible to inhibit metal atoms from diffusing from the source-drain silicide in the direction indicated by arrow in FIG. 8 while forming the full silicide gate 403. In this manner, the junction leak (JL) can be further reduced.

(Fifth Embodiment)

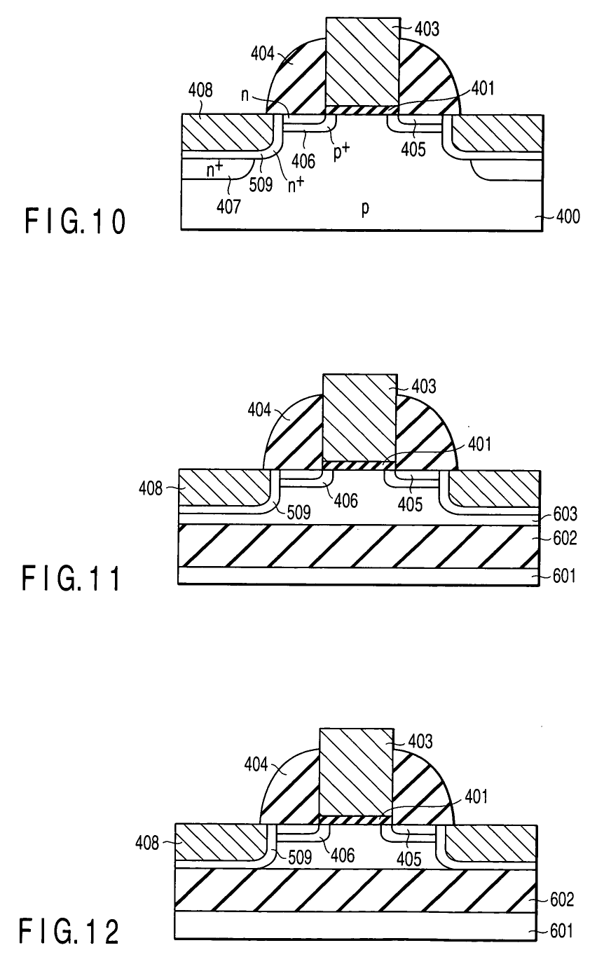

FIG. 10 is a cross sectional view of an element structure of a MIS type field effect transistor according to the fifth embodiment of the present invention. It should be noted that the structural elements of this embodiment that are similar to those shown in FIG. 8 are designated by the same reference numerals and the detailed descriptions therefor will be omitted here.

This embodiment can be regarded as a remodeled version of the fourth embodiment. That is, the structure shown in FIG. 10 is substantially identical to that of the fourth embodiment except that it includes an n⁺-type high concentration impurity layer (the third semiconductor region) 509.

The structure of this embodiment can be realized by carrying out the formation of the source-drain region in a similar manner to that of the second embodiment in the respective step of the manufacturing method of the fourth embodiment. Further, the n⁺-type high concentration impurity layer 509 has a steep concentration profile as described in connection with the first embodiment as well. In this manner, the junction leak (JL) can be suppressed further than the case of the fourth embodiment.

(Sixth Embodiment)

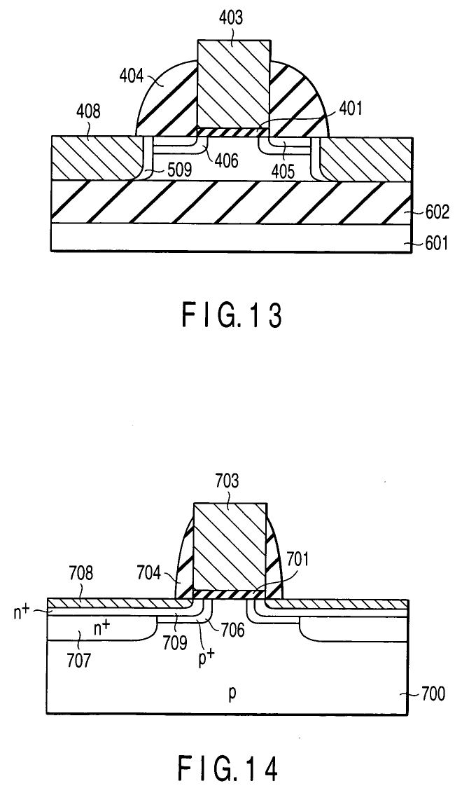

FIGS. 11 to 13 are cross sectional views of an element structure of a MIS type field effect transistor according to the sixth embodiment of the present invention. It should be noted that the structural elements of this embodiment that are similar to those shown in FIG. 8 are designated by the same reference numerals and the detailed descriptions therefor will be omitted here.

In this embodiment, an SOI substrate including a silicon substrate layer 601, a buried insulating film 602 and a silicon layer 603 formed further thereon, is used to suppress junction leak (JL) from the bottom surface of the source-drain region. In this case, however, the thickness of the channel region and the sputtering amount of Ni need be appropriately adjusted.

As in the cases of FIGS. 5 to 7 described before in connection with the third embodiment, there are possible modified versions for this embodiment as shown in FIGS. 11 to 13. These modified versions are able to further reduce the JL than the case of the fifth embodiment. Further, the full silicide gate structure is employed in these modified versions, and therefore these versions are able to further reduce the JL than the case of the third embodiment.

(Seventh Embodiment)

FIG. 14 is a cross sectional view of an element structure of a MIS type field effect transistor according to the seventh embodiment of the present invention. It should be noted that the structural elements of this embodiment that members 700 to 708 shown in FIG. 8 correspond to the members 100 to 108 shown in FIG. 1.

This embodiment is an example in which the concept of the present invention is applied to a Schottky transistor. When the invention is applied to Schottky transistors, the problem of a great amount of junction leak (JK) can be solved without loss of the advantages of the Schottky transistors.

In this embodiment, there is no n-type extension diffusion layer 405, but in place, a source-drain electrode is formed on both sides of the channel region. The source-drain electrode is formed of a source-drain silicide 708 and an n-type high concentration impurity layer 709 formed by segregation to silicide. Further, the gate 703 is made of full silicide.

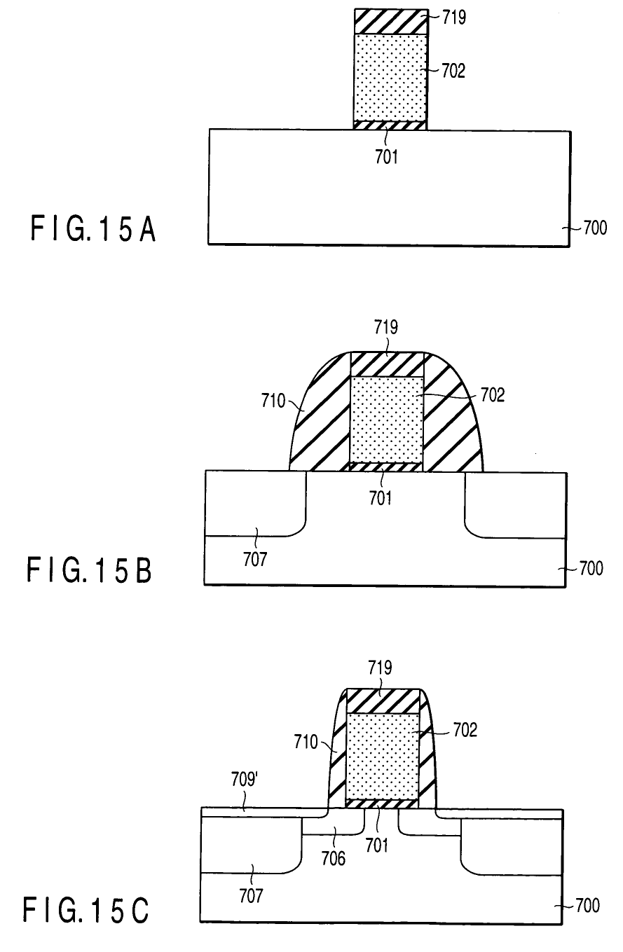

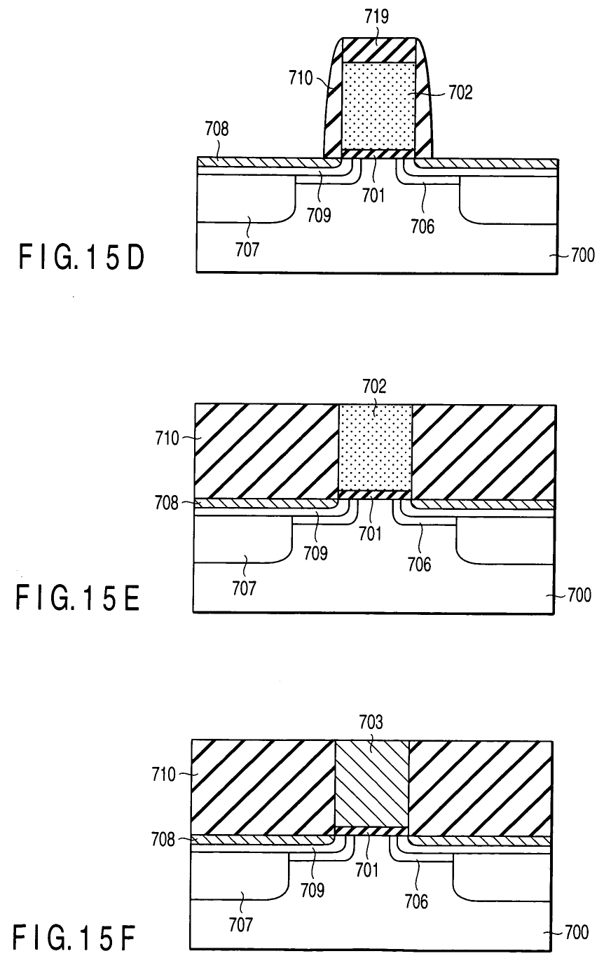

Next, the method of manufacturing the field effect transistor of this embodiment will now be described with reference to FIGS. 15A to 15F.

First, an element isolation region (not shown) is formed on the p-type silicon substrate (first semiconductor region) 700, and then, the gate insulating film 701 is formed to have a thickness of about 1 nm in terms of EOT, as shown in FIG. 15A. A polysilicon film having a thickness of about 100 to 150 nm is deposited as the gate electrode 702, and further a silicon nitride film 719 having a thickness of about 100 nm is deposited as a gate protecting film. Then, the gate protecting film 719, the gate electrode 702 and the gate insulating film 701 are processed into a gate electrode pattern by the lithography technique, RIE, etc. If necessary, a post oxidation of about 1 to 2 nm is carried out here.

Next, as shown in FIG. 15B, a TEOS film is deposited to have a thickness of about 30 nm by the reduced pressure chemical vapor deposition (LP-CVD) method, and then the resultant is etched back by the RIE method to form a dummy gate sidewall TEOS film 710. Subsequently, As is ion-implanted as an impurity to have a concentration of about 2×10¹⁵ cm⁻² in the substrate 700, and thus a deep diffusion layer 707, is formed.

After that, as shown in FIG. 15C, the dummy gate sidewall TEOS film 710 is subjected to, for example, the DHF process, to be slimmed. As an alternative to the slimming, it is possible to completely remove the film and then deposit a new film. Subsequently, BF₂ and As are ion-implanted to form a HALO diffusion layer 706 and an impurity layer 709′, which gives rise to the high-concentration impurity layer. Further, spike anneal is carried out here at 1030° C. to activate the impurities.

Next, as shown in FIG. 15D, Co is sputtered to have a thickness of about 9 nm, and then a heat treatment is carried out at 500° C. for 30 seconds. In this manner, silicon of the source and drain is silicided, thereby forming a source-drain silicide 708. Here, at the same time, the impurity in the layer 709′is segregated under the influence of the siliciding, and thus a n⁺-type high concentration impurity layer 709 is formed in the interface between the source-drain silicide 708 and the silicon substrate 700. After that, unreacted Ni is removed. It should be noted here that the high concentration impurity layer 709 is not segregated from the silidice to the substrate but segregated inside the silicide. In other word, the high concentration impurity layer 709 is formed in the interface on the substrate side of the source-drain electrode.

Subsequently, as shown in FIG. 15E, a TEOS oxide film and the like are deposited as an interlayer insulating film 110, and then the upper surface of the gate electrode 702 is exposed by the CMP.

Next, as shown in FIG. 15F, Ni is sputtered to have a thickness of about 20 nm, and then a heat treatment is carried out at 450° C. for about 30 seconds, thereby siliciding the entire silicon in the gate electrode 702. Thus, the full silicide gate 703 made of nickel silicide is formed. After that, unreacted Ni is removed, and thus such a structure as shown in FIG. 14 is obtained.

As described above, according to this embodiment, there is provided a Schottky transistor structure which contains the high concentration impurity layer 709 formed by segregation of the impurity into the silicide, between the source-drain electrode 708 and the channel region. With this structure, the junction leak (JL) occurring near the gate edge can be reduced. Therefore, the punch through and leas current can be suppressed, and the reliability of the element can be improved.

(Eighth Embodiment)

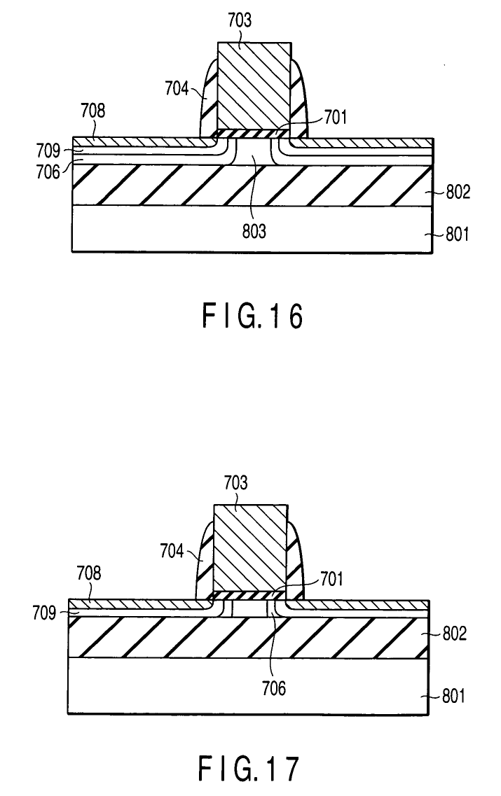

FIGS. 16 to 18 are cross sectional views of an element structure of a MIS type field effect transistor according to the eighth embodiment of the present invention. It should be noted that the structural elements of this embodiment that are similar to those shown in FIG. 14 are designated by the same reference numerals and the detailed descriptions therefor will be omitted here.

In this embodiment, an SOI substrate including a silicon substrate layer 801, a buried insulating film 802 and a silicon layer 603 formed further thereon, is used to suppress junction leak (JL) from the bottom surface of the source-drain region. In this case, however, the thickness of the channel region and the sputtering amount of Ni need be appropriately adjusted.

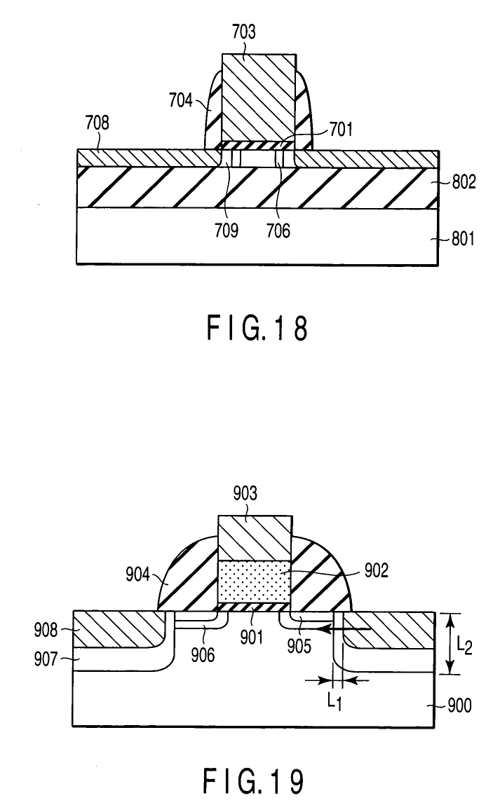

As in the cases of FIGS. 5 to 7 described before in connection with the third embodiment, there are possible modified versions for this embodiment as shown in FIGS. 16 to 18. In the version shown in FIG. 16, the deep diffusion layer 707 is not necessary and the HALO diffusion layer 706 is in contact with the buried insulating film 802. On the other hand, in the version shown in FIG. 17, the high-concentration impurity layer 709 is in contact with the buried insulating film 802. Further, in the version shown in FIG. 18, the source-drain silicide 708 is in contact with the buried insulating film 802. These modified versions are able to further reduce the JL than the case of the seventh embodiment.

(Modified Examples)

It should be noted that the present invention is not limited to the embodiments described above. In the above-described embodiments, silicon is used as a semiconductor substrate material, but the invention is not limited to the use of silicon only, but also, for example, silicon germanium (SiGe), germanium (Ge), silicon carbide (SiC), gallium arsenide (GaAs) and aluminum nitride (AlN) can be used. Further, it is not always necessary that the first semiconductor region and second semiconductor region should be of the opposite conduction types to each other, but they may be of the same conduction type with different impurity concentrations.

Further, the plane orientation of the substrate material is not necessarily limited to the (100) plane, but (110) plane, (110) plane, etc. can be selected in accordance with necessity. Furthermore, the present invention is applicable to the three dimensional type such as the Fin-type structure and the double gate structure, and thus it can be applied to any type of MIS field effect transistor.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A field effect transistor comprising:
a first semiconductor region of a first conduction type, on which a channel region is formed;
a gate electrode formed on the channel region of the first semiconductor region with a gate insulating film being formed between the gate electrode and the channel region;
source and drain electrodes formed on the first semiconductor region with the channel region of the first semiconductor region being interposed between the source and drain electrodes in a channel length direction;
second semiconductor regions of a second conduction type formed between each of the source and drain electrodes and the channel region, each of the second semiconductor regions forming an extension region of each of the source and drain electrodes; and
third semiconductor regions of the second conduction type formed between each of the source and drain electrodes and each of the first semiconductor region and the second semiconductor region, each of the third semiconductor regions formed by segregation from the source and drain electrodes and having an impurity concentration higher than that of the second semiconductor regions.

2. The field effect transistor according to claim 1, wherein the first semiconductor region is formed of a semiconductor layer formed on a buried insulating film.

3. The field effect transistor according to claim 2, wherein each part of the third semiconductor regions is in direct contact with the buried insulating film.

4. The field effect transistor according to claim 2, wherein a part of each of the source and drain electrodes is in direct contact with the buried insulating film.

5. The field effect transistor according to claim 1, further comprising fourth semiconductor regions of the first conduction type formed between the first semiconductor region and the second semiconductor regions, and having an impurity concentration higher than that of the first semiconductor region.

6. The field effect transistor according to claim 1, further comprising fifth semiconductor regions of the second conduction type formed between a bottom part of the third semiconductor regions and the first semiconductor region.

7. The field effect transistor according to claim 1, wherein the gate electrode being made of Ni silicide and each of the source and drain electrodes being made of Co silicide.

8. A method of manufacturing a field effect transistor, the method comprising:
forming a gate electrode on a part of a first semiconductor region of a first conduction type with a gate insulating film interposed between the gate electrode and the part of the first semiconductor region;
forming second semiconductor regions of a second conduction type on the first semiconductor region with the gate electrode arranged between the second semiconductor regions by ion-implanting an impurity using the gate electrode as a mask, the second semiconductor regions forming source and drain extension regions, respectively;
forming sidewall insulating films on opposite side surfaces of the gate electrode after formation of the second semiconductor regions;
ion-implanting an impurity to the first semiconductor region using the gate electrode and the sidewall insulating films as a mask to form ion-implanted parts;
forming source and drain electrodes by siliciding selectively the first semiconductor region to an area deeper than the ion-implanted part; and
forming third semiconductor regions of the second conduction type having an impurity concentration higher than that of the second semiconductor regions, in an interface between each of the source and drain electrodes and each of the first semiconductor region and the second semiconductor regions, by segregation from the source and drain electrodes.

9. The manufacturing method according claim 8, further comprising: forming fourth semiconductor regions of the first conduction type having an impurity concentration higher than that of the first semiconductor region, at a position deeper than that of the second semiconductor regions, by ion-implanting a different impurity from that used to form the second impurity region in the first semiconductor region using the gate electrode as a mask immediately before or after formation of the second semiconductor regions.

10. The manufacturing method according claim 8, wherein a semiconductor layer formed on a buried insulating film is used as the first semiconductor region.

11. The manufacturing method according claim 10, wherein each part of the third semiconductor layers is formed between each of the source and drain electrodes and the buried insulating film by carrying out the siliciding for forming the source and drain electrodes until immediately before contacting the buried insulating film.

12. The manufacturing method according claim 10, wherein the siliciding for forming the source and drain electrodes is carried out until contacting the buried insulating film.

13. A field effect transistor comprising:
a first semiconductor region of a first conduction type on which a channel region is formed;
a gate electrode formed on the channel region of the first semiconductor region with a gate insulating film interposed between the gate electrode and the channel region;
source and drain electrodes formed on the first semiconductor region with the channel region of the first semiconductor region being interposed between the source and drain electrodes in a channel length direction, the source and drain electrodes being formed of a metal silicide; and
impurity segregation regions of a second conduction type formed between the first semiconductor region and each of the source and drain electrodes, the impurity segregations region being formed by segregation of the impurity into the metal silicide.

14. The field effect transistor according to claim 13, further comprising second semiconductor regions of a second conduction type formed between each of the source and drain electrodes and the first semiconductor region.

15. The field effect transistor according to claim 13, wherein the first semiconductor region is formed of a semiconductor layer formed on a buried insulating film.

16. The field effect transistor according to claim 15, wherein each part of the impurity segregation regions is in direct contact with the buried insulating film.

17. The field effect transistor according to claim 13, further comprising third semiconductor regions of the first conduction type formed between the impurity segregation regions and the first semiconductor region, and having an impurity concentration higher than that of the first semiconductor region.

18. The field effect transistor according to claim 13, wherein the gate electrode being made of Ni silicide and each of the source and drain electrodes being made of Co silicide.

19. A method of manufacturing a field effect transistor, the method comprising:
forming a gate electrode on a part of a first semiconductor region of a first conduction type with a gate insulating film interposed between the gate electrode and the first semiconductor region;
forming sidewall insulating films on opposite sides of the gate electrode;
forming second semiconductor regions of a second conduction type in the first semiconductor region by ion-implanting an impurity to the first semiconductor region using the gate electrode and the sidewall insulating films as a mask;
slimming or removing the sidewall insulating films after the formation of the second semiconductor regions;
adding an impurity of a second conduction type in an area of a surface portion of the first semiconductor region to a level shallower than the second semiconductor regions using the gate electrode as a mask after slimming or removing the sidewall insulating films; and
forming source and drain electrodes by siliciding selectively the surface portion of the first semiconductor region, where the second conduction type impurity is added, and forming segregation regions of the second conduction type between the first semiconductor region and each of the source and drain electrodes by segregation of the impurity into the source and drain electrodes.
